(19) United States
(12) Patent Application Publication
(10) Pub. No.: US 2025/0236488 A1
(43) Pub. Date: Jul. 24, 2025

(54) ELEVATOR SAFETY APPARATUS AND ELEVATOR WITH SAID SAFETY APPARATUS

(71) Applicant: KONE CORPORATION, Helsinki (FI)

(72) Inventor: Mikko Paakkinen, Helsinki (FI)

(73) Assignee: KONE CORPORATION, Helsinki (FI)

(21) Appl. No.: 19/175,276

(22) Filed: Apr. 10, 2025

Related U.S. Application Data
(63) Continuation of application No. PCT/EP2022/080783, filed on Nov. 4, 2022.

(51) Int. Cl. B66B 5/00; B66B 1/34; G01R 31/52; H02K 11/27

(52) U.S. Cl. CPC B66B 5/0031; B66B 1/3446; G01R 31/52; H02K 11/27

(57) ABSTRACT

The present disclosure describes an elevator safety apparatus. The safety apparatus comprises an elevator hoisting motor for driving an elevator car in elevator shaft between landing floors, switches connected between all the phases of the motor for causing a short circuit between the phases, and a monitoring device configured for monitoring presence of the short circuit at all said motor phases.

### FIELD

The present invention relates to elevator safety arrangements and to ensuring proper functioning of said safety arrangements.

### BACKGROUND

Elevators have electromechanical hoisting machinery brakes as safety devices to apply braking force to a traction sheave or a rotating axis of a hoisting machinery of an elevator car. There is at least one, in many cases at least two, separate brakes working in tandem. These brakes are dimensioned to hold standstill an elevator car while the car idle, as well as to stop elevator car movement in case of an operational anomaly. Such an operational anomaly may be an overload situation of an elevator car, undesired movement of an elevator car within a landing, or an overspeed situation of an ascending elevator car, for example.

Braking force of the electromechanical hoisting machinery brakes may be compromised e.g., because of a wrong brake component, wear of the brakes, or an error in conducting elevator maintenance. A misconduct in brake adjustment process or foreign matter, such as oil, getting into the braking surfaces are some examples of such errors. Inadequate braking force may also be caused by an error in elevator masses, causing excessive unbalancing torque on a traction sheave of an elevator hoisting machine.

Inadequate braking force may lead to undesired movement, i.e., undesired drifting of elevator car despite the hoisting machinery brakes engaged. Such undesired movement may be dangerous for elevator users during normal elevator operation, as well as for maintenance personnel working in elevator shaft outside of the normal operation periods.

Consequently, there is a need for complementary safety measures to ensure safe elevator operation.

### SUMMARY

The objective of the invention is to solve one or more of the afore-mentioned problems. Therefore, the following disclosure will bring forward a complementary safety solution for the hoisting machinery brakes. The complementary solution introduces a short circuit connected between the windings of an elevator hoisting motor.

The aforementioned short circuit is a safety measure that prevents an excessive acceleration or velocity of elevator car in case of hoisting machinery brake failure. This is based on the fact that, in elevator motors (which are usually permanent magnet motors), rotation of the rotor causes electromotive force (emf), which further causes current in case the motor windings shorted. Said short circuit current, often referred to as “dynamic braking current”, causes braking torque that brakes movement of an elevator car.

The short circuit may be provided with a monitoring device that continuously monitors that short circuit loop is intact and prevents elevator starting if circuit is tampered. The monitoring device may inject high frequency alternating voltage to the motor windings and measure respective current. The presence or lack of presence of the short circuits in the phases is determined based on the measured currents. If a short circuit in some or all phases is missing, the start of the elevator is prevented. By means of the monitoring device, the presence of the short circuit can be verified, and thus the presence of said complementary safety measure in elevator may be confirmed. The monitoring device can be implemented with a simple circuit without software. In this manner, continuous monitoring without a special testing mode can be achieved. Preferably, the monitoring device is configured for monitoring presence of the short circuit at all said motor phases when the elevator is stopped, i.e., power supply to the hoisting motor has been interrupted and elevator brakes have been engaged.

### BRIEF DESCRIPTION OF THE DRAWINGS

FIG. 1 shows a simplified diagram of an exemplary elevator arrangement with an embodiment of a safety apparatus according to the present disclosure.

FIG. 2A shows an exemplary embodiment of a test voltage generation unit according to the present disclosure.

FIG. 2B shows a simplified representation of the test voltage generation and current sensing circuitry for one phase.

FIG. 2C shows an exemplary embodiment of a detection unit used to detect presence of short circuit.

FIG. 2D shows a comparison unit utilizing a timer signal that is synchronous to the generated square-wave test voltage.

### DETAILED DESCRIPTION

The present disclosure introduces an elevator safety apparatus and an elevator arrangement with said safety apparatus. An elevator arrangement according to the present disclosure comprises an elevator hoisting motor for driving an elevator car in elevator shaft between landing floors. The hoisting motor is preferably a synchronous permanent magnet motor because it is able to generate the electromotive force without a need for an additional energy source for magnetization. The motor may be driven with drive unit that supplies power to the phase windings of the motor, for example. The drive unit is typically a frequency converter.

The elevator arrangement may be provided with a safety apparatus that resists undesired movement, such as drifting of the elevator car. This safety apparatus may act as a complementary safety measure to hoisting machinery brakes of the elevator arrangement. The safety apparatus may comprise switches, such as relays or contactors, that are connected between all the motor phases. With the switches a short circuit can be caused between the phases. The switches realize a dynamic brake that may be used as a complementary safety measure. As mentioned earlier, rotation of the rotor of the hoisting motor causes a dynamic braking current in the short-circuited windings, which in turn causes braking torque that resists movement of the rotor in case of machinery brake failure. The switches may be configured to operate responsive to a safety output signal. The type of the switches may be normally closed (NC), i.e., the switches may be in conducting state unless set to non-conductive state with an active signal. In this manner, the safety feature is on by default even if the safety output signal is malfunctioning or if external power supply to the elevator system has failed or has been interrupted. The safety output signal may originate from elevator control. The elevator control may contain the drive unit (typically a frequency converter), as well as a main control board handling normal elevator functions, such that handling elevator service requests. Further, elevator control may include safety control, such as a programmable electronic safety controller complying with safety integrity level 3 (SIL 3), in accordance with functional safety standard IEC 61508.

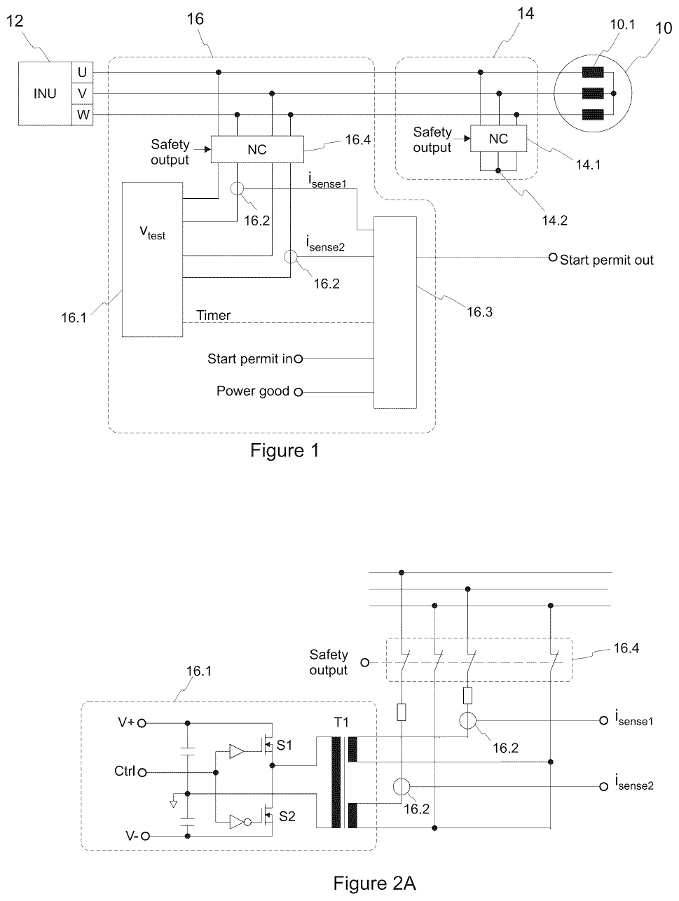

FIG. 1 shows a simplified diagram of an exemplary an elevator arrangement with an embodiment of a safety apparatus according to the present disclosure. In the elevator arrangement of FIG. 1, three-phase windings 10.1 of a hoisting motor 10 are driven with an inverter unit 12 of a frequency converter. The motor 10 may be a permanent magnet synchronous motor, PMSM, for example. The safety apparatus in FIG. 1 comprises a short circuit arrangement 14, that comprises a first switch arrangement 14.1 through which the phases of the motor 10 are connectable to a short circuit 14.2. The switching arrangement 14.1 may comprise normally closed relays or contactors, for example. In other words, the phases 10.1 of the motor 10 are short-circuited by default. In this manner, the safety apparatus is always on unless the switches are actively opened with the safety output signal (shown as “Safety output” in FIG. 1), e.g., to proceed to normal operation. At a failure and during a test mode or when elevator is idle (outside at the end of elevator run and outside normal operation, i.e., in those times when the hoisting machinery brakes are applied), the switches 14.1 are closed to short the phases together.

For additional safety, the safety apparatus may comprise a monitoring device that monitors automatically that the safety apparatus is functioning correctly. The monitoring device may be configured to monitor presence of the short circuits at all said motor phases. The short circuit arrangement of the safety apparatus is configured such that each short circuit forms a low-inductance current route bypassing the normal route through the windings of the motor. As a result, the presence (or lack of presence) of the short circuit can be detected by monitoring the impedance of the connection between the windings. Said monitoring can take place by means of an impedance meter that is configured to measure resistance and/or inductance of the short circuit.

To determine or approximate the impedance of the connection between the windings, the monitoring device preferably implements the functionality of an inductance meter configured for measuring short circuit inductance. The monitoring device may be configured to supply an AC test voltage to said motor phases, measure a current response caused by the AC test voltage, and then determine presence of short circuit based on an inductive component of said response current. In this context, the AC test voltage may be a periodic voltage that is injected to the motor phases. For example, the AC test voltage may be a square-wave or a sinusoidal signal. If at least one response current has a substantial inductive component, then it is concluded that at least one of the short circuit contacts is erroneously open, and the integrity of the dynamic braking function is compromised. In this case elevator start is prevented, otherwise elevator start is allowed. For this reason, the device also provides an indication of the presence/non-presence of the short circuit to the elevator control. In some embodiments, this indication may take the form of a permission signal, as will become apparent later in this disclosure.

There are different approaches for determining the inductive component of the current response. For example, the monitoring device may comprise current sensing circuitry configured to determine the amplitude of the current response and determine the presence of the short circuits based on the amplitude. The frequency of the AC voltage may be selected such that the amplitude of the current response is detectably lower if the current has to pass through the high-inductance route via the windings of the motor. For example, the frequency of the AC test may be at least, or preferably higher than, the switching frequency of a frequency converter driving the hoisting motor. For example, if the switching frequency of the frequency converter is about 5-10 KHz, the frequency of the AC test voltage may be in range of 50-100 kHz, or even higher (e.g., 150 kHz). As a result, a large current amplitude value may be used as an indication of the current passing through a low impedance route whereas a small current amplitude value may be used for indicating the current passing through a high-impedance route.

FIG. 1 shows one example of a monitoring device 16 according to the present disclosure. The monitoring device 16 in FIG. 1 is connected the phases of the motor 10 in order to monitor the short circuits. The monitoring device 16 comprises a test voltage generator unit 16.1 that supplies AC test voltages to the phases of the motor 10. The monitoring device 16 further comprises current sensors 16.2 in order to measure current responses caused by the AC test voltages. The current sensors 16.2 may be in the form of hall-effect sensors, shunt resistors or voltage dividers, for example. The monitoring device 16 further comprises a detection unit 16.3 that determines the presence of the short circuit based on inductive components of said response currents and generates indications of the existence/non-existence of the short circuits.

This monitoring may take place at the end of elevator run and outside normal operation, i.e., at those times when the hoisting machinery brakes have been applied. During those times no power is supplied to the hoisting motor, and the complementary safety measure in the form of the short circuit should be present in the motor phases. For normal operation, the monitoring device can be separated from the motor phases. In order to achieve this, the monitoring device 16 in FIG. 1 comprises a second switch arrangement 16.4. Similar to the first switch arrangement 14.1, the second switch arrangement 16.4 may comprise normally closed relays or contactors, for example. In this manner, the monitoring device 16 is separable from the phases with the safety output signal. When safety output is inactive, the normally closed contacts are closed, and monitoring starts automatically. Alternatively, the second switch arrangement 16.4 may comprise normally open relays/contactors such, that they are closed only for the duration of the test.

Switching state of the second switch arrangement 16.4. may also be determined by means of the monitoring device 16 such that, if there is no current in response to applied test voltage, switches of the second switch arrangement 16.4. are deemed to be in open state.

In FIG. 1, the detection unit 16.3 also has “Start permit in” signal as an input. This signal, also called a “permission signal” in this disclosure, may represent a permission to proceed to starting the elevator. The permission signal may originate from another control or detection unit that controls or monitors the functional status of the elevator, such as the safety control included in the elevator control, for example. The detection unit 16.3 may then modify the permission signal based on the detected presence of the short circuit. If no fault is detected in the short circuit, the detection unit may let the signal pass unaltered. However, if detection unit 16.3 detects that the short circuit is missing in one or more phases, it may alter the permission signal to indicate that starting the elevator is not permitted. The detection unit 16.3 also has a “Power Good” signal as an input. This signal may represent the status of the supply voltage (or voltages) powering the safety apparatus according to the present disclosure. The detection unit 16 may be configured such that if the supply voltage (or voltages) is not at above its set minimum level, the detection unit prevents the elevator from starting by preventing the “Start permit” signal from proceeding forward.

FIG. 1 also shows an optional “Timer” signal between the test voltage generator unit 16.1 and the detection unit 16.3. The “Timer” signal may represent a synchronization signal indicating frequency and phase of the test signal generated by the test voltage generator 16. In some embodiments, the detection unit 16.3 may utilize this signal in determining the inductive component detectable in the current response.

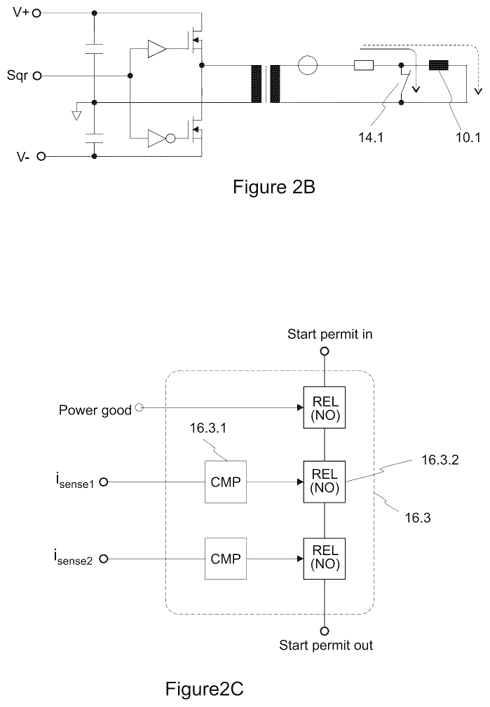

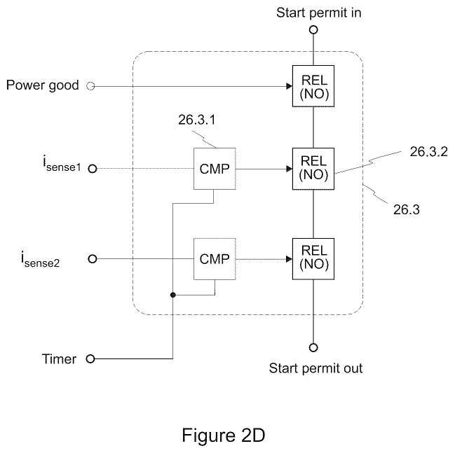

In the following, some aspects of the safety apparatus according to the present disclosure are discussed in more detail in view of exemplary embodiments. FIGS. 2A to 2D show some of these embodiments.

For example, FIG. 2A shows an exemplary embodiment of the test voltage generation unit. The test voltage generation unit 16.1 utilizes a small-power high-frequency circuit (signal generator+transformer driver+transformer) that injects a square wave voltage with a duty cycle of 50% between motor phases. One advantage of using a square wave is that it can be produced with relatively few components. The signal generator (not shown in the Figures) generates a control signal controlling transformer driver. In FIG. 2A, the control signal is in the form of signal “Ctrl”. The control signal may be in the form of a square wave alternating at a high frequency. In FIG. 2A, the transformer driver is a half bridge formed between a positive supply voltage V+ and a negative supply voltage V−. The half bridge in FIG. 2A is implemented with transistor (MOSFET) switches S1 and S2. The gates of the switches S1 and S2 are provided with a non-inverting and inverting buffer so that only one of the switches is in conducting state at a time. As a result, a square-wave signal alternating between the positive supply voltage V+ and the negative supply voltage V− is supplied to the primary winding of the transistor T1. While FIG. 2A shows a transformer with a single primary winding and two secondary windings and a single driver circuit driving the primary windings, the test voltages can also be generated independently. For example, both test voltages may have their own transformer and transformer driver (and even signal generator).

The test voltage generation unit 16.1 supplies the phases of the motor 10 with the test voltage, presence of the short circuit (formed by the short circuit arrangement 14) may be determined based on the current response to the test voltage. If a short circuit fails to form or opens in at any of the connection points, at least one of the induced currents has to pass through the transformer windings. Due to the high impedance, transformer secondary current is in that case very small. FIG. 2B shows a simplified representation of the test voltage generation and current sensing circuitry for one phase. In FIG. 1, a complete circuit from driver to motor windings is shown. In the actual implementation, however, both test voltages may be generated with the same transformer driver. The transformer driver in FIG. 2B generates a square-wave test voltage to the primary winding of the transformer.

On the secondary side of the transformer, if the phase is short-circuited, the current passes through a low-inductance route through the switch 14.1 of the short circuit arrangement 14. As a result, the currents caused by the test voltage remain largely square-shaped and have high amplitudes on the secondary side of the transformer, because they are able to pass through the low-inductance short circuit (the amplitudes may be mainly limited by loop resistors in the current route) However, if the short circuit loop is open in a phase, the current has to pass through the stator winding 10.1 (route shown with a dashed line). In this case, the current waveform of the respective sensor is triangular and the amplitude is much lower because the inductive load of stator winding 10.1.

FIG. 2C shows an exemplary embodiment of the detection unit 16.3 used to detect the presence of the short circuit and to modify the permission signal when necessary. The detection unit 16.3 comprises comparison units 16.3.1 that form estimates of the amplitude of a current through a phase, compare the estimates to a threshold level, and output indicator signals representing the results of the comparisons. A window comparator may be used, for example. If the amplitude of the alternating current signal remains within the defined window, the short circuit is determined to be not present in the phase in question. On the other hand, if the current signal reaches values beyond the defined window, the short circuit is determined to be present in the phase.

Alternatively, the detection unit 16.3 may first rectify them and filter the rectified signal with a low-pass filter, for example. As a result, a (non-alternating) estimate representing the amplitude of the sensed current can be formed. This amplitude estimate signal may be compared with the threshold level in order to decide whether a short circuit is present in said phase.

In another embodiment, the comparison units may utilize a timer signal that is synchronous to the generated square-wave test voltage. FIG. 2D shows such an embodiment. In the detection unit 26.3, the comparison unit 26.3.1 also receives the timer signal as an input. The control signal of the transformer driver may act as the timer signal, for example. The timer signal may be compared with the current measurement signals to determine the presences of the short circuits in the phases. For example, the current measurements may first be turned into binary signals with comparators, and then compared with the timer signal by using logic circuits (e.g., XNOR). If the generated binary signal and the timer signal correlate well, a short circuit may be concluded to be present in the respective phase. Conversely, if the generated binary signal does not correlate with the timer signal, the short circuit is not present in said phase. The result of the comparison between the timer signal and the generated binary signal is used to control a relay 26.3.2 in a relay chain similar to the chain in the earlier embodiments.

Finally, in order to modify the permission signal based on the comparison results, the detection unit 16.3 implements a chain of normally open (NO) relays 16.3.2 through which the permission signal has to pass. If the comparison signal from the comparison unit 16.3.1 indicates that the current exceeds the set limit, the respective relay is closed, and the permission signal is able to pass through the relay. Similarly, the “Power Good” signal controls a normally open relay in the relay chain such that the permission signal is able to pass the relay only when the supply voltage (or voltages) exceed its set minimum level. Because the relays form a daisy chain, the permission signal is able to pass through the whole chain (and therefore, through the detection unit 16.3) only when the “Power Good” signal is at an acceptable level and both current signals indicate that their respective phases are in short-circuited.

While the above embodiments discuss using the amplitude of the current response as the indicator of the presence (or lack of presence) of short circuit, the monitoring device according to the present disclosure is not limited only to such implementations. Alternatively, or in addition, a phase shift between the injected AC voltage and the current result may be determined and the presence of the short circuit may be based on the phase shift. Further, while the above embodiments mostly discuss determining the presence of a short circuit based on the inductive component of the impedance of the connection between the windings, the presence of the short circuit may also be determined based on the resistance of the connection.

Further, while the above-discussed embodiments relate to implementations comprising only discrete components, the functionalities of the monitoring device and monitoring method according to the present disclosure may also be implemented using a computing device, such as programmable logic (e.g., an FPGA), a microcontroller, or a processor. The computing device may be configured to control a transformer driver (e.g., as described in the previous embodiments) to supply an AC test voltage to the motor phases of the hoisting motor. The monitoring device may further comprise an A/D converter configured to measure the current response. The computing device may be configured to receive these measurements from the A/D converter and determine an inductive component in said response current and the presence of short circuit based on the inductive component. For example, the computing device may determine the inductive component based on the amplitude and/or the phase shift of the current response as discussed above.

1. An elevator safety apparatus, comprising
an elevator hoisting motor for driving an elevator car in elevator shaft between landing floors;
switches connected between all the phases of the motor for causing a short circuit between the phases; and
a monitoring device configured for monitoring presence of the short circuit at all said motor phases.

2. An elevator safety apparatus according to claim 1, wherein the monitoring device is an impedance meter configured for measuring short circuit impedance.

3. An elevator safety apparatus according to claim 2, wherein the monitoring device is an inductance meter configured for measuring short circuit inductance.

4. An elevator safety apparatus according to claim 2, wherein the monitoring device is configured to
supply an AC test voltage to said motor phases
measure a current response caused by the AC test voltage, and
determine presence of short circuit based on an inductive component of said response current.

5. An elevator safety apparatus according to claim 1, wherein the monitoring device is further configured to
provide a signal representing a permission to start normal operation on the condition that the short circuit was determined to be present.

6. An elevator, comprising:
an elevator car adapted for moving in elevator shaft between landing floors, and
the elevator safety apparatus according to claim 1.

7. A safety method for an elevator, wherein the method comprises
causing a short circuit between motor phases of a hoisting motor of the elevator together with a set of switches provided between the motor phases,
supplying AC test voltage between phases of the motor,
monitoring a current response caused by the test voltage,
determining presence of a short circuit based on an inductive component of said response current.

8. A safety method according to claim 7, wherein the method comprises, on the condition that a short circuit was confirmed,
opening the switches to disconnect the short circuit, and providing a signal representing a permission to start normal operation.

9. An elevator safety apparatus according to claim 3, wherein the monitoring device is configured to
supply an AC test voltage to said motor phases
measure a current response caused by the AC test voltage, and
determine presence of short circuit based on an inductive component of said response current.

10. An elevator safety apparatus according to claim 2, wherein the monitoring device is further configured to
provide a signal representing a permission to start normal operation on the condition that the short circuit was determined to be present.

11. An elevator safety apparatus according to claim 3, wherein the monitoring device is further configured to
provide a signal representing a permission to start normal operation on the condition that the short circuit was determined to be present.

12. An elevator safety apparatus according to claim 4, wherein the monitoring device is further configured to
provide a signal representing a permission to start normal operation on the condition that the short circuit was determined to be present.

13. An elevator, comprising:
an elevator car adapted for moving in elevator shaft between landing floors, and
the elevator safety apparatus according to claim 2.

14. An elevator, comprising:
an elevator car adapted for moving in elevator shaft between landing floors, and
the elevator safety apparatus according to claim 3.

15. An elevator, comprising:
an elevator car adapted for moving in elevator shaft between landing floors, and
the elevator safety apparatus according to claim 4.

16. An elevator, comprising:
an elevator car adapted for moving in elevator shaft between landing floors, and
the elevator safety apparatus according to claim 5.
